(19) United States
(12) Patent Application Publication
(10) Pub. No.: US 2024/0186173 A1
(43) Pub. Date: Jun. 6, 2024

(54) TRANSFER METHOD FOR OPTOELECTRONIC SEMICONDUCTOR COMPONENT

(71) Applicant: ams-OSRAM International GmbH, Regensburg (DE)

(72) Inventor: Alexander Pfeuffer, Regensburg (DE)

(21) Appl. No.: 18/552,610

(22) PCT Filed: Apr. 1, 2022
(86) PCT No.: PCT/EP2022/058758

§ 371 Date: Sep. 26, 2023

(30) Foreign Application Priority Data
Apr. 1, 2021 (DE) 10 2021 108 397.4

(51) Int. Cl. H01L 21/683; H01L 25/075; H01L 33/60; H01L 33/62

(52) U.S. Cl. CPC H01L 21/6835; H01L 25/0753; H01L 33/60; H01L 33/62; H01L 2221/68354; H01L 2221/68368; H01L 2933/0066

(57) ABSTRACT

In embodiments a method includes providing an optoelectronic semiconductor component on the first carrier, applying a structurable material layer on the at least one optoelectronic semiconductor component, structuring the at least one structurable material layer in such a way that a partial region of the structured material layer on a top surface of the optoelectronic semiconductor component is assigned to the optoelectronic semiconductor component; picking up the optoelectronic semiconductor component by a transfer unit, lifting the optoelectronic semiconductor component off the first carrier, arranging the optoelectronic semiconductor component on a first region of the second carrier, wherein at least a second region adjacent to the first region on the second carrier protrudes the top surface of the optoelectronic semiconductor component and fixing the optoelectronic semiconductor component to the second carrier.

### CROSS-REFERENCE TO RELATED APPLICATIONS

This patent application is a national phase filing under section 371 of PCT/EP2022/058758, filed Apr. 1, 2022, which claims the priority of German patent application 10 2021 108 397.4, filed Apr. 1, 2021, each of which is incorporated herein by reference in its entirety.

### TECHNICAL FIELD

The present invention relates to a method for transferring at least one optoelectronic semiconductor component from a first carrier to a second carrier. In particular, the present invention relates to a method for generating an electrical and mechanical connection between an optoelectronic semiconductor component and a printed circuit board. Furthermore, the present invention relates to an optoelectronic intermediate product which is generated, in particular, during a process for transferring at least one optoelectronic semiconductor component from a first carrier to a second carrier and is subsequently further processed.

### BACKGROUND

Thermocompression bonding is a common approach for electrically and mechanically bonding an optoelectronic semiconductor component to, for example, a printed circuit board. In this process, for example, a force is applied to a top surface of the optoelectronic semiconductor component opposite the printed circuit board by means of a mostly rigid plate, thereby pressing the optoelectronic semiconductor component onto the printed circuit board. Optionally, the optoelectronic semiconductor component can be heated via the plate so that the optoelectronic semiconductor component arranged on the printed circuit board is electrically and mechanically connected to it.

Such a process is known, for example, from U.S. Pat. No. 81,0060 B2 and the non-patent literature “Review of Electrically Conductive Adhesive Technologies for Electronic Packaging” by Myung Jin Yim, and Kyung Wook Paik.

However, if the optoelectronic semiconductor component is transferred into a deeper cavity or a cavity, or if the optoelectronic semiconductor component is surrounded by protrusions or further components which protrude the optoelectronic semiconductor component as seen in the vertical direction, it may be difficult to apply a necessary pressure to the top surface of the optoelectronic semiconductor component. In particular, it may be difficult to apply a necessary pressure to the top surface of the optoelectronic semiconductor component by means of a large-area plate, since this would collide with the elevations or further components surrounding the optoelectronic semiconductor component. As a result, it is correspondingly not possible to apply the necessary pressure to the top surface of the optoelectronic semiconductor component in order to generate a sufficient electrical and mechanical connection between the printed circuit board and the optoelectronic semiconductor component arranged thereon.

### SUMMARY

Embodiments provide a method for transferring at least one optoelectronic semiconductor component from a first carrier to a second carrier and, in particular, a method for generating an electrical and mechanical connection between an optoelectronic semiconductor component and a printed circuit board, by means of which optoelectronic semiconductor components can be applied reliably, simply and inexpensively even to surfaces with a raised topography (e.g. a cavity).

A method according to the invention for transferring at least one optoelectronic semiconductor component from a first carrier to a second carrier comprises the steps:
Providing at least one optoelectronic semiconductor component on a first carrier;
Applying a structurable material layer to the at least one optoelectronic semiconductor component arranged on the first carrier;
Structuring, in particular in the form of an etching process, of the at least one structurable material layer in such a way that a partial region of the structured material layer on a top surface of the optoelectronic semiconductor component is assigned to the optoelectronic semiconductor component;
Picking up the optoelectronic semiconductor component by means of a transfer unit (e.g. stamp) comprising a placement of the transfer unit on a top surface of the partial region of the structured material layer opposite to the optoelectronic semiconductor component;
Lifting the optoelectronic semiconductor component from the first carrier;
arranging the optoelectronic semiconductor component on a first region of a second carrier, wherein at least a second region on the second carrier adjacent to the first region protrudes the top surface of the optoelectronic semiconductor component; and
Fixing the optoelectronic semiconductor component to the second carrier.

An essential aspect of the invention is that the structured material layer can compensate surface topographies on the second carrier so that sufficient pressure can be applied to the optoelectronic semiconductor component during the fixing step. In particular, the sum of the thicknesses of the material layer and the semiconductor component may be selected to be equal to the height of the second regions or even greater. Thus, the mechanical and electrical connection of the optoelectronic semiconductor component with the second carrier can be improved, even if the optoelectronic semiconductor component is arranged in a cavity or surrounded by other raised elevations or components. Accordingly, the structured material layer can compensate for a height difference between an optoelectronic semiconductor component and a structure surrounding the optoelectronic semiconductor component by having the top surface of the structured material layer protruding above the surrounding structures. Thus, a desired pressure can be applied to the structured material layer or the optoelectronic semiconductor component in a simple and reliable manner.

Also, the structured material layer can planarize or smooth out outcoupling structures on the top surface of the optoelectronic semiconductor component. This reduces damage or erosion of the top surface during the steps of lifting off, arranging and fixing the optoelectronic semiconductor component. This can be the case in particular if the structured material layer has a lower hardness than individual layers of the optoelectronic semiconductor component, or the structured material layer has a lower hardness than at least the outcoupling structures on the top surface of the optoelectronic semiconductor component.

In some embodiments, the top surface of the partial region of the structured material layer protrudes the at least one second region after the optoelectronic semiconductor component is arranged on the first region. Accordingly, the top surface of the structured material layer may protrude the structures surrounding the optoelectronic semiconductor component. The top surface can thus be easily accessible, and a force can be applied to the top surface of the structured material layer in a simple manner, for example, by means of a substantially rigid and large-area plate.

In some embodiments, the first region forms a bottom surface of a cavity and the at least one second region forms a surface of a rim forming the cavity. Accordingly, the at least one optoelectronic semiconductor component may be arranged in a cavity on the first region, wherein the top surface of the at least one optoelectronic semiconductor component is arranged within and does not protrude the cavity when the optoelectronic semiconductor component is arranged in the cavity. In other words, the cavity or the optoelectronic semiconductor component may be formed and arranged in the cavity such that a height of the optoelectronic semiconductor component is less than a vertical extent of the cavity. In particular, the top surface of the optoelectronic semiconductor component may be below the top surface of the rim forming the cavity. For example, the height of the optoelectronic semiconductor component may be at most one-half or at most three-quarters of the vertical extent of the cavity.

The cavity can be reflective, for example. The optoelectronic semiconductor component can be surrounded by the cavity or a cavity structure, whereby the side walls of the cavity or the cavity structure can be designed to be reflective. Thus, on the one hand, an improved light guidance with increased power of a light emitted by the optoelectronic semiconductor component is achieved, and, on the other hand, a crosstalk between several optoelectronic semiconductor components is prevented or at least significantly reduced.

However, the second region may also be formed by the top surface of an elevation or by the top surface of a further component arranged on the printed circuit board. Without the structured material layer on the top surface of the optoelectronic semiconductor component, the second region or the top surface of the elevation or the further component could correspondingly collide with a substantially rigid plate by means of which a force is applied to the top surface of the structured material layer. However, this is to be prevented by the structured material on the top surface of the optoelectronic semiconductor component.

In some embodiments, the step of fixing the optoelectronic semiconductor component comprises pressing the optoelectronic semiconductor component onto the second carrier. Optionally, the step of fixing the optoelectronic semiconductor component additionally comprises heating the optoelectronic semiconductor component. In particular, the step of fixing the optoelectronic semiconductor component can be performed according to the steps of a thermo-compression bonding (TCB) process.

In some embodiments, the step of fixing the optoelectronic semiconductor component includes applying a solder system to the semiconductor component and/or to the second carrier and then soldering.

In some embodiments, the step of fixing the optoelectronic semiconductor component is performed using a substantially rigid plate. The plate may be formed from a plurality of layers having different degrees of hardness. In particular, a layer of the plate facing the optoelectronic semiconductor component may be softer than the other layers of the plate. Also, a layer of the plate facing the optoelectronic semiconductor component may be formed softer than the top surface of the structured material layer. For example, at least one of the plurality of layers may be formed by a film, in particular a soft and optionally temporarily applied film. This can, for example, reduce damage to or erosion of the top surface of the structured material layer during the step of fixing the optoelectronic semiconductor component.

In some embodiments, the second carrier is formed by a printed circuit board or backplane. In particular, the second carrier may be formed by a multilayer ceramic substrate or a silicon wafer. In some embodiments, the substrate may be formed with electrical terminals thereon. In particular, the second substrate may comprise thin film transistors.

The first carrier may, for example, be formed by a wafer or a grow-on substrate. The at least one optoelectronic semiconductor component may have been grown on the first carrier, for example. In particular, a plurality of optoelectronic semiconductor component s may have been grown on the first carrier and may be spaced 2 μm to 3 μm apart from each other on the first carrier.

In some embodiments, the first region comprises a contact pad and the optoelectronic semiconductor component is arranged on the contact pad. A surface of the contact pad may be provided with conductive or non-conductive adhesive (isotropic or anisotropic). Alternatively, a direct connection, in particular a metal-to-metal connection, can be made without adhesive between the contact pad and the optoelectronic semiconductor component. Likewise, it is conceivable that a solder is applied to the contact pad and that the step of fixing the optoelectronic semiconductor component comprises a soldering process.

In some embodiments, the method comprises a further step in the form of removing at least a portion of the partial region of the structured material layer. The structured material layer or at least a portion of the structured material layer can be applied accordingly in the form of a sacrificial layer to the optoelectronic semiconductor component and can be at least partially removed again after the step of fixing the optoelectronic semiconductor component. The step of removing at least a part of the partial region of the structured material layer can thereby be carried out with the aid of solvents, ozonized water, a plasma treatment and/or with the aid of an ashing process.

In some embodiments, the step of structuring the at least one structurable material layer comprises applying a photostructurable resist to the structurable material layer and subsequently structuring the photostructurable resist and the structurable material layer such that a portion of the structured material layer on a top surface of the optoelectronic semiconductor component is associated with the optoelectronic semiconductor component. The photostructurable resist can be removed again before the step of picking up the optoelectronic semiconductor component by means of a transfer unit or remain on the structurable material layer.

In some embodiments, the structurable material layer is formed by a sacrificial layer that is only temporarily arranged on the optoelectronic semiconductor component and that is at least partially removed after the step of fixing the optoelectronic semiconductor component.

In some embodiments, the structurable material layer itself comprises a photostructurable resist, in particular a photoresist. This may be the case, in particular, if the structurable material layer is only temporarily arranged on the optoelectronic semiconductor component and is at least partially removed again after the step of fixing the optoelectronic semiconductor component.

The structured material layer can, for example, be designed in such a way that damage to or erosion of the top surface of the optoelectronic semiconductor component can be reduced during the steps of lifting off, arranging and fixing the optoelectronic semiconductor component. This can be the case in particular if the structured material layer has a lower hardness than individual layers of the optoelectronic semiconductor component, or the structured material layer has a lower hardness than the top surface of the optoelectronic semiconductor component.

The structurable material layer may be characterized, for example, by good temperature stability and/or pressure stability in order not to damage the structurable material layer or the optoelectronic semiconductor component when fixing the optoelectronic semiconductor component to the second carrier, for example under increased pressure and/or increased temperature.

In some embodiments, the structurable material layer comprises an at least partially transparent material, such as a parylene or a silicone. In particular, at least a portion of the structurable material layer comprising an at least partially transparent material may be permanently/permanently arranged on the top surface of the optoelectronic semiconductor component.

In some embodiments, the structurable material layer has light-converting and/or light-scattering particles. These particles or other materials may serve to convert or scatter light. Thus, for example, desired light properties and a desired radiation characteristic of the optoelectronic semiconductor component can be achieved.

In some embodiments, the partial region of the structured material layer surrounds the optoelectronic semiconductor component as viewed in a circumferential direction. Accordingly, the partial region of the structured material layer is arranged on the top surface of the optoelectronic semiconductor component and, in addition thereto, surrounds the optoelectronic semiconductor component in a circumferential direction of the optoelectronic semiconductor component. In particular, at least the part of the structured material layer surrounding the optoelectronic semiconductor component may be arranged permanently/permanently on the optoelectronic semiconductor component and may, for example, comprise light-converting and/or light-scattering particles.

In some embodiments, the partial region of the structured material layer includes regions that are permanently/permanently arranged on the optoelectronic semiconductor component and regions that are only temporarily arranged on the optoelectronic semiconductor component.

In some embodiments, the step of depositing the structurable material layer includes a spin-on process, a sputtering or spin-on process, or a similar process suitable therefor.

In some embodiments, the structurable material layer exhibits good thermal conductivity such that good heat transfer occurs from a plate applied to the top surface of the structurable material layer or to the top surface of the portion of the structured material layer and heated to the at least one optoelectronic semiconductor component.

In some embodiments, the at least one optoelectronic semiconductor component is formed by an optoelectronic light source, in particular an LED. The optoelectronic semiconductor component or the optoelectronic light source can, for example, have an edge length of less than 300 μm, in particular less than 150 μm. At these spatial extents, the at least one optoelectronic semiconductor component or the optoelectronic light source is virtually invisible to the human eye.

In some embodiments, the at least one optoelectronic semiconductor component is an LED. In particular, the LED may be referred to as a mini-LED, which is a small LED, for example, with edge lengths of less than 200 μm, in particular down to less than 40 μm, in particular in the range of 200 μm to 10 μm. Another range is between 150 μm to 40 μm.

The LED may also be referred to as a micro-LED, also known as a μLED, or a μLED chip, particularly in the case where the edge lengths are in the range of 70 μm to 10 μm. In some embodiments, the LED may have a spatial dimension of 90×150 μm or a spatial dimension of 75×125 μm.

In some embodiments, the mini-LED or μLED chip may be an unhoused semiconductor chip. Unhoused may mean that the chip does not have a package around its semiconductor layers, such as a die. In some embodiments, unhoused may mean that the chip is free of any organic material. Thus, the unhoused device does not contain any organic compounds that contain carbon in a covalent bond.

In some embodiments, the at least one optoelectronic semiconductor component is formed by a light source capable of emitting light of a particular color. In some embodiments, a plurality of optoelectronic semiconductor component s may be configured to emit light having different colors, such as red, green, blue, and yellow. However, the at least one optoelectronic semiconductor component may also be formed by a sensor, in particular a photosensitive sensor.

In some embodiments, the described process is used to transfer multiple optoelectronic semiconductor components from the first carrier to the second carrier simultaneously. In particular, the described method can be used to simultaneously fix multiple optoelectronic semiconductor components to the second carrier using, for example, a rigid plate in the form of a TCB process.

An optoelectronic intermediate product according to the invention comprises a printed circuit board having at least one first region and at least one second region adjacent to the first region, and at least one optoelectronic semiconductor component arranged on the at least one first region. A partial region of a structured material layer or sacrificial layer is arranged on a top surface of the at least one optoelectronic semiconductor component. The at least one second region protrudes the top surface of the optoelectronic semiconductor component and a top surface of the partial region of the structured material layer or sacrificial layer opposite the optoelectronic semiconductor component protrudes the at least one second region.

In particular, the optoelectronic intermediate product may be an intermediate product of the process described above. In particular, the intermediate product may be generated during a process for transferring at least one optoelectronic semiconductor component from a first carrier to a second carrier and subsequently processed further.

In some embodiments, the optoelectronic intermediate product further comprises a contact pad arranged between the first region and the optoelectronic semiconductor component.

In some embodiments, the structured material layer or sacrificial layer comprises a photoresist. However, the structured material layer can also be formed by another material that can be easily removed, thus forming a sacrificial layer that can be easily removed after fixing the optoelectronic semiconductor component to a carrier.

In some embodiments, the structured sacrificial layer comprises an at least partially transparent material, such as a parylene or a silicone.

In some embodiments, the structured sacrificial layer comprises light-converting and/or light-scattering particles.

### BRIEF DESCRIPTION OF THE DRAWINGS

In the following, embodiments of the invention are explained in more detail with reference to the accompanying drawings.

FIG. 1 shows a sectional view of a optoelectronic semiconductor component and its simplified illustration;

FIG. 2 shows process steps of a method for transferring optoelectronic semiconductor components from a first carrier to a second carrier;

FIG. 3 shows process steps of a further process for transferring optoelectronic semiconductor components from a first carrier to a second carrier;

FIGS. 4A and 4B show process steps of a method for transferring optoelectronic semiconductor components from a first carrier to a second carrier according to some aspects of the proposed principle; and

FIGS. 5A and 5B show a sectional view of a optoelectronic semiconductor component according to some aspects of the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size to highlight individual aspects. It will be understood that the individual aspects and features of the embodiments and examples shown in the figures may be readily combined with each other without affecting the principle of the invention. Some aspects have a regular structure or shape. It should be noted that minor deviations from the ideal shape may occur in practice, but without contradicting the inventive idea.

In addition, the individual figures, features and aspects are not necessarily shown in the correct size, nor do the proportions between the individual elements have to be fundamentally correct. Some aspects and features are highlighted by showing them enlarged. However, terms such as “above”, “above”, “below”, “below”, “larger”, “smaller” and the like are correctly represented in relation to the elements in the figures. Thus, it is possible to derive such relationships between the elements based on the figures.

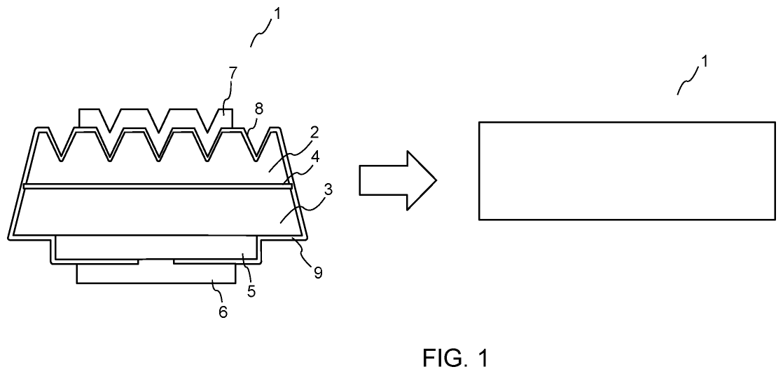

FIG. 1 shows a sectional view of an optoelectronic semiconductor component 1 or LED chip and a simplified representation of the LED chip. The LED chip can be understood as a semiconductor layer stack which has a negatively doped layer of a semiconductor material (n-layer) 2 and a positively doped layer of a semiconductor material (p-layer) 3. During doping, the semiconductor crystal is deliberately “contaminated” with impurity atoms in order to change its conductivity. This leads to an electron excess in the n-layer and an electron deficiency (holes) in the p-layer. As soon as an appropriate current is connected to the semiconductor crystal in the forward direction, the excess electrons of the n-layer 2 migrate towards the p-layer 3. In a so-called active region 4, they meet the holes of the p-layer 3. There, the migrated electrons and the holes start to recombine. This recombination generates energy, which radiates in the form of light flashes (photons) and emerges from the semiconductor crystal in the form of light waves. The active region 4 can be formed as a layer, but also as a quantum well, multiple quantum well, with a quantum dot structure or any other structure designed for radiative recombination.

A first electrical contact 5 is formed below the p-layer, which can also act as a mirror, and a contact pad 6 is formed on the first electrical contact 5. A second electrical contact 7 is formed on the top of the semiconductor layer stack, so that the LED chip can be supplied with electrical energy via the two contacts. In addition, the semiconductor layer stack has a light outcoupling structure 8 on its top surface, by means of which the light outcoupling efficiency of the LED chip can be increased. The second electrical contact 7 is designed in such a way that it imitates the structure of the light decoupling structure 8 and accordingly also has a corresponding structure on its top surface. The semiconductor layer stack also has a dielectric material 9 which envelops the semiconductor stack.

Shown in the figure on the right is a simplified representation of such an optoelectronic semiconductor component 1 as used in the further figures.

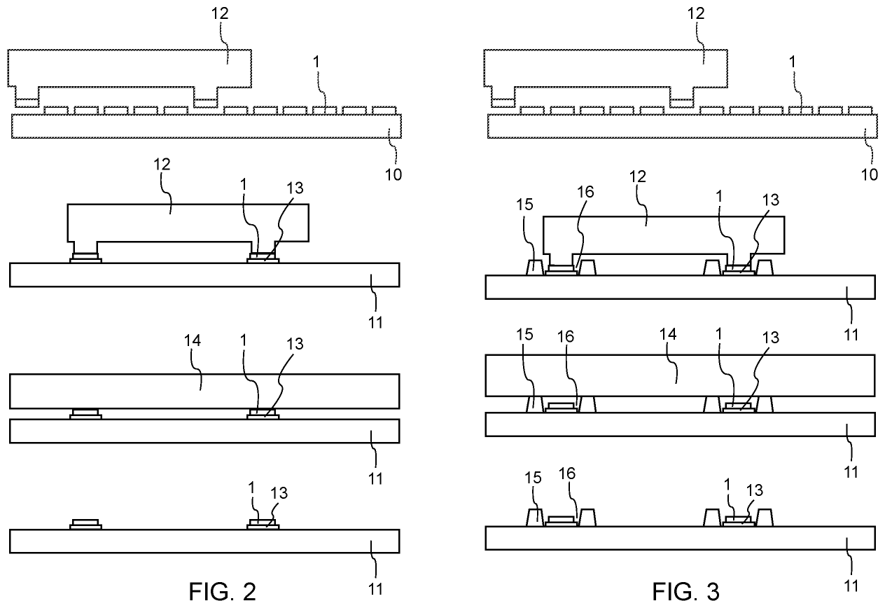

FIG. 2 shows process steps of a process for transferring optoelectronic semiconductor components 1 from a first carrier 10 to a second carrier 11. In a first step, the optoelectronic semiconductor components 1 are lifted off the first carrier 10 by means of a transfer unit (e.g. stamp) 12, and then, in a second step, the optoelectronic semiconductor components 1 are arranged on the second carrier 11 by means of the transfer unit or the stamp 12 on contact pads 13 provided for this purpose.

In a further step, the optoelectronic semiconductor components 1 are then fixed to the second carrier 11 by means of a TCB process by applying a defined pressure to the top surface of the optoelectronic semiconductor components 1 by means of a plate 14, for example a plate made of silicone. Optionally, the optoelectronic semiconductor components 1 can also be heated by means of the plate 14, so that a sufficiently good mechanical and electrical connection is created between the optoelectronic semiconductor components 1 and the second carrier. The final product is shown in the figure below.

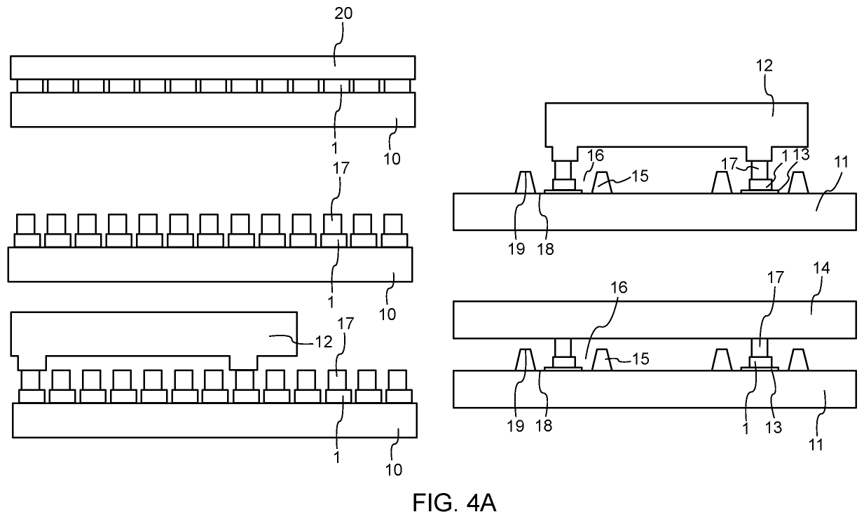

FIG. 3 shows process steps of a further process for transferring optoelectronic semiconductor components 1 from a first carrier 10 to a second carrier 11. In contrast to the process shown in FIG. 1, however, the second carrier 11 has elevations 15 or cavities 16 formed by the elevations 15. The optoelectronic semiconductor components 1 are arranged by means of the transfer unit 12 in a second step on the second carrier 11 in a respective cavity 16 on a respective contact pad 13 provided for this purpose.

However, due to the protrusions 15 projecting above the optoelectronic semiconductor components 1, it is not possible to fix the optoelectronic semiconductor components 1 to the second substrate 11 by means of a TCB process as shown in the previous figure. The plate 14 described in the preceding figure collides with the protrusions 15 when attempting to apply a pressure to the top surface of the optoelectronic semiconductor components 1, so that they are neither pressed onto the contact pad 13 nor heated via the plate 14. This results in a connection between the optoelectronic semiconductor components 1 and the second carrier 11 or the contact pads 13 being created only by the step of arranging the optoelectronic semiconductor components 1 by means of the transfer unit 12. However, this cannot achieve a sufficiently good mechanical and electrical connection between the optoelectronic semiconductor components 1 and the second carrier 11.

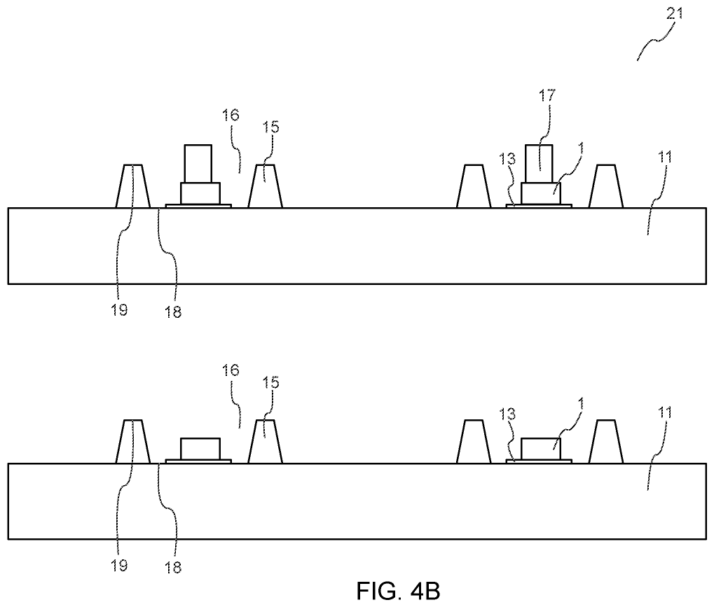

FIGS. 4A and 4B show process steps of a method for transferring optoelectronic semiconductor components 1 from a first carrier 10 to a second carrier 11 according to some aspects of the proposed principle. According to FIG. 4A, in this process, in a first step, a structurable material layer 20 is applied to the top surface of a plurality of optoelectronic semiconductor components 1 arranged on a first carrier 10 in spaced relationship to each other. Subsequently, this material layer 20 is structured by means of, for example, a photolithography process, so that each optoelectronic semiconductor component 1 is assigned only a partial region 17 of the structured material layer on the top surface of the optoelectronic semiconductor component.

In a further step, several optoelectronic semiconductor components 1 are picked up by means of a transfer unit 12 and transferred to the second carrier 11. In the present case, two optoelectronic semiconductor components 1 are picked up and transferred to the second carrier 11 as an example. On the second carrier 11, the optoelectronic semiconductor components 1 are each arranged in a cavity 16 on a respective contact pad 13 provided therefor. In this case, the optoelectronic semiconductor components 1 have a lower height than the elevations 15 forming the cavities 16, so that the top surfaces of the optoelectronic semiconductor components 1 each lie within the cavity. Compared to the top surface of the elevations 15, the top surfaces of the optoelectronic semiconductor components 1 lie offset downwardly, so to speak, relative to the latter. The respective bottom of a cavity 16 thereby forms a first region 18 and the top surface of the elevations 15 in each case forms a second region 19. The optoelectronic semiconductor components 1 or contact pads 13 are arranged accordingly on the first region 18 and the second region 19 in each case protrudes the top surfaces of the optoelectronic semiconductor components 1.

The partial regions 17 of the structured material layer have such a height that the top surface of the partial regions 17 lies above the top surface of the elevations 15 or above the second region 19. The optoelectronic semiconductor components 1 are subsequently fixed to the second carrier 11 by means of a TCB process, by applying a defined pressure to the top surface of the partial regions 17 of the structured material layer by means of a plate 14. Optionally, the optoelectronic semiconductor components 1 can be heated by means of the plate 14 over the partial regions 17 of the structured material layer, so that a sufficiently good mechanical and electrical connection between the optoelectronic semiconductor components 1 and the second carrier is generated.

The resulting intermediate product 21, as shown in FIG. 4B above, comprises the second carrier 11, in particular in the form of a printed circuit board, and the two optoelectronic semiconductor components 1 which are arranged on the second carrier respectively on the contact pad 13 and on the first region 18. Elevations 15 are formed on the second carrier 11, which protrudes the optoelectronic semiconductor components 1, so that the top surface of the elevations 15 or a second region 19 in each case protrudes the top surface of the optoelectronic semiconductor components 1. A partial region 17 of the structured material layer or sacrificial layer is arranged on the top surface of the optoelectronic semiconductor components 1 in each case, so that the top surface of a partial region 17 of the structured material layer or sacrificial layer protrudes the second region 19 in each case.

The partial regions 17 of the structured material layer may be removed in a further step as shown in FIG. 4B below, but the partial regions may also remain at least partially on the optoelectronic semiconductor components 1.

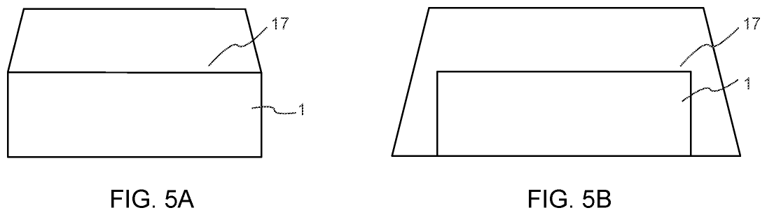

Such a case is shown, for example, in FIG. 5A and FIG. 5B. In this case, the partial regions 17 of the structured material layer are designed in such a way that they remain on the optoelectronic semiconductor components 1 after the step of fixing the optoelectronic semiconductor components 1 on the second carrier 11. Accordingly, the partial regions 17 of the structured material layer can remain permanently on the optoelectronic semiconductor components 1. The partial regions 17 of the structured material layer can in particular also have light-shaping or light-scattering properties. This can be achieved on the one hand by the shape of the subregions 17 of the structured material layer (here exemplarily in the form of a trapezoid) or by light-scattering particles in the material layer.

As shown in FIG. 5B, the partial regions 17 of the structured material layer can also be designed in such a way that they surround the optoelectronic semiconductor components 1 as seen in a circumferential direction. This can be particularly advantageous if the material layer has light-converting particles, since in this way light emitted from the optoelectronic semiconductor components to the side must also pass through the material layer and thus the light can be converted.

1.-20. (canceled)

21. A method for transferring at least one optoelectronic semiconductor component from a first carrier to a second carrier, the method comprising:
providing an optoelectronic semiconductor component on the first carrier;
applying a structurable material layer on the at least one optoelectronic semiconductor component arranged on the first carrier;
structuring the at least one structurable material layer in such a way that a partial region of the structured material layer on a top surface of the optoelectronic semiconductor component is assigned to the optoelectronic semiconductor component;
picking up the optoelectronic semiconductor component by a transfer unit comprising a placement of the transfer unit on a top surface of the partial region of the structured material layer opposite the optoelectronic semiconductor component;
lifting the optoelectronic semiconductor component off the first carrier;
arranging the optoelectronic semiconductor component on a first region of the second carrier, wherein at least a second region adjacent to the first region on the second carrier protrudes the top surface of the optoelectronic semiconductor component; and
fixing the optoelectronic semiconductor component to the second carrier,
wherein the top surface of the partial region of the structured material layer protrudes the at least one second region after the optoelectronic semiconductor component is arranged on the first region.

22. The method according to claim 21, wherein the first region forms a bottom surface of a cavity and the at least one second region forms a surface of a rim forming the cavity.

23. The method according to claim 21, wherein fixing the optoelectronic semiconductor component comprises pressing the optoelectronic semiconductor component onto the second carrier and optionally heating the optoelectronic semiconductor component.

24. The method according to claim 21, wherein fixing the optoelectronic semiconductor component is conducted by a substantially rigid plate, the plate optionally being formed of a plurality of layers having different degrees of hardness.

25. The method according to claim 21, wherein the second carrier is a printed circuit board.

26. The method according to claim 21, wherein the first carrier is a wafer or a growth substrate.

27. The method according to claim 21, wherein the first region comprises a contact pad, and wherein the optoelectronic semiconductor component is arranged on the contact pad.

28. The method according to claim 21, further comprising removing at least a portion of the partial region of the structured material layer.

29. The method according to claim 21, wherein the structurable material layer comprises a photoresist.

30. The method according to claim 21, wherein the structurable material layer comprises an at least partially transparent material, and wherein the partially transparent material is parylene or silicone.

31. The method according to claim 21, wherein the structurable material layer comprises light-converting and/or light-scattering particles.

32. The method according to claim 21, wherein the partial region of the structured material layer surrounds the optoelectronic semiconductor component as viewed in a circumferential direction.

33. The method according to claim 21, wherein applying the structurable material layer comprises a spin-on process or sputtering.

34. The method according to claim 21, wherein a plurality of optoelectronic semiconductor components are simultaneously transferred from the first carrier to the second carrier.

35. An optoelectronic intermediate product comprising:
a printed circuit board having at least one first region and at least one second region adjacent to the first region;
at least one optoelectronic semiconductor component arranged on the at least one first region; and
a partial region of a structured sacrificial layer arranged on a top surface of the at least one optoelectronic semiconductor component,
wherein the at least one second region protrudes above the top surface of the optoelectronic semiconductor component, and
wherein a top surface of the partial region of the structured sacrificial layer opposite the optoelectronic semiconductor component protrudes the at least one second region.

36. The optoelectronic intermediate product according to claim 35, further comprising a contact pad arranged between the first region and the optoelectronic semiconductor component.

37. The optoelectronic intermediate product according to claim 35, wherein the structured sacrificial layer comprises a photoresist.

38. The optoelectronic intermediate product according to claim 35, wherein the structured sacrificial layer comprises an at least partially transparent material, and wherein the partially transparent material is parylene or silicone.

39. The optoelectronic intermediate product according to claim 35, wherein the structured sacrificial layer comprises light-converting and/or light-scattering particles.
